(19) United States
(12) Patent Application Publication
(10) Pub. No.: US 2009/0255725 A1
(43) Pub. Date: Oct. 15, 2009

(54) Integrated Wi-Fi Service Enclosure

(76) Inventor: David Curtis, (US)

Correspondence Address: RAYMON L. FASNACHT, 423 LOS RIOS COURT, PLEASANTON, CA, 94566, US

(21) Appl. No.: 12/103,552

(22) Filed: Apr. 15, 2008

(51) Int. Cl. H05K 7/14; H05K 7/00; H04B 7/14

(52) U.S. Cl. 174/535; 455/90.3; 455/7

(57) ABSTRACT

An in-wall enclosure for housing a wireless network device and broadband connectivity equipment together. The enclosure is attached to a wall stud in a location pre-determined to be the optimum place to maximize wireless coverage within the structure. An electrical outlet is wired to the enclosure to provide power. Cables for the broadband network connection are also pre-wired to the enclosure. After construction is complete, a wireless network device (Wi-Fi router, access point, or similar device) and a broadband connection device (DSL modem, cable modem, broadband wireless modem, or similar device) are installed in the enclosure. Once installed and configured, the wireless router then provides seamless wireless coverage throughout the dwelling or business office. The front panel is attached to cover the recessed enclosure to provide a smooth, professionally finished appearance on the interior wall.

### FIELD OF THE INVENTION

The present invention relates to structured wiring enclosures used in building construction and, more particularly, to systems for designing, installing, and managing wireless local area networks for home and business.

### BACKGROUND OF THE INVENTION

The installation of a wireless network is not usually considered in the design or construction phases of new buildings. If someone wants a wireless local area network in their home, they usually install a wireless access point/router at the same location as their main computer. This is typically in their home office which is often located in a spare bedroom in the far corner of the home, nowhere near the physical center of the structure.

Several problems exist in this scenario. First, existing wiring infrastructure often has to be upgraded to enable high-speed networking. This is very cumbersome, severely limits the choices where the wiring can be terminated and often cannot be accomplished without opening up walls or running wire outside the home. Second, the wireless router and broadband modem have to be placed near the broadband connection, usually sitting on the floor in an obtrusive manner. And, most importantly, installation of a wireless access point at these locations does not provide the maximum wireless coverage over the entire footprint of the structure.

Current structured wiring boxes only have room for cable terminating blocks and are made of steel.

No other solution has been derived to easily and effectively locate the wireless network device and the broadband connectivity equipment in the same location to simplify installation and provide optimum network coverage.

What is needed therefore is a single, polyvinyl enclosure to house a wireless networking device and broadband connection equipment for designing wireless networking into new construction, simplifying installation, and ultimately providing optimum wireless network coverage.

It would be advantageous to provide a single enclosure to house a wireless networking device and broadband connectivity equipment to simplify installation and improve the performance of wireless local area networks in residential and business environments.

It would also be advantageous to provide an enclosure made of polyvinyl or similar material to further enhance wireless signal propagations.

It would further be advantageous to provide an enclosure that recesses the networking equipment into a wall to make them unobtrusive.

It would further be advantageous to provide an opening in the top of the enclosure to enable the wireless device and/or its antennas to protrude into the open wall space from within the enclosure if desired.

It would further be advantageous to provide screw holes in the back panel of the enclosure that align with mounting slots on various wireless networking devices and broadband connectivity devices to simplify installation of these into the enclosure.

It would further be advantageous to provide front-edge alignment guides on the outside walls of the enclosure to ensure that the enclosure is installed at the desired depth relative to the drywall that is typically installed after the enclosure.

It would further be advantageous to provide an opening for a gang box to terminate an electrical outlet in the enclosure.

It would further be advantageous to provide an opening in the bottom, top, or side wall of the enclosure to route network cables in to and out of the enclosure.

It would further be advantageous to provide mounting holes on the sides of the enclosure to simplify mounting the enclosure to a wall stud utilizing screws or nails.

### SUMMARY OF THE INVENTION

In accordance with the present invention, there is provided an enclosure made of polyvinyl or similar material that has ample space to house a wireless networking device and broadband connectivity equipment to co-locate this equipment inside a wall such that maximum wireless network coverage is provided throughout a structure.

The enclosure consists of an in-wall receptacle and a front cover. The in-wall receptacle includes a back panel and four side walls around the perimeter, together forming a rectangular enclosure with the sixth side remaining open. The cover is used to close this opening and can be detachable or hinged to the receptacle.

The in-wall receptacle has an opening at the top to allow the wireless device and/or its antennas to protrude into the open wall space if desired. It has two openings on the bottom, one to accommodate a gang box with an electrical outlet, the other to route networking cables into the receptacle. Screw holes on the back panels are used to mount the wireless device and the broadband equipment inside the receptacle. Two mounting holes on each side are provided to attach the receptacle to a wall stud on one side or the other. Front-edge alignment guides are attached on the outside of each side wall to set against the stud to align the receptacle properly relative to the drywall.

### BRIEF DESCRIPTION OF THE DRAWINGS

A complete understanding of the present invention may be obtained by reference to the accompanying drawings, when considered in conjunction with the subsequent, detailed description, in which:

FIG. 1 is an exploded view of an one embodiment of the invention showing the components of the integrated wi-fi service enclosure and how the front cover can attach to the in-wall receptacle using screws and the threaded inserts;

FIG. 2 is a front view of an embodiment of the in-wall receptacle component of an integrated wi-fi service enclosure;

FIG. 3 is a front view of a receptacle in FIG. 2, shown with a wi-fi router and a broadband modem in place within the receptacle, the electrical outlet installed, and the receptacle mounted on a wall stud;

FIG. 4 is a top view of a receptacle in FIG. 2 showing the opening for the router and its antennas; and

FIG. 5 is a left view of a receptacle in FIG. 2 showing the front-edge alignment guides and stud mounting holes.

For purposes of clarity and brevity, like elements and components will bear the same designations and numbering throughout the Figures.

### DESCRIPTION OF THE PREFERRED EMBODIMENT

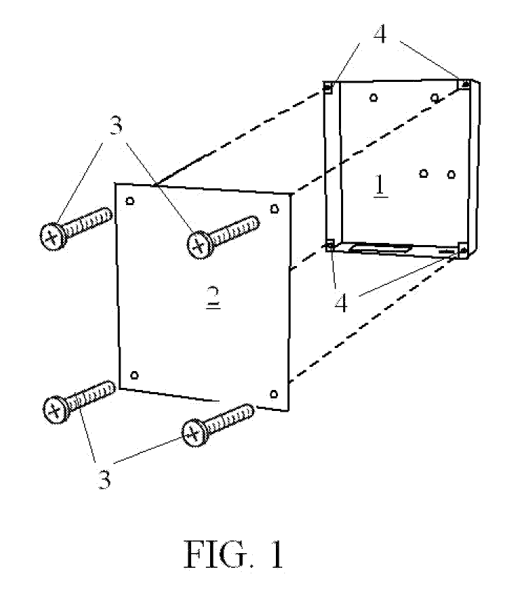

Referring now to the drawings, in which like element numbers refer to like elements throughout. FIG. 1 is an exploded view of the entire integrated Wi-Fi service enclosure comprised of the front cover 2 and the in-wall receptacle 1. In this embodiment, the front cover 2 attaches to the in-wall receptacle 1 by securing the four cover screws 3 into the threaded inserts 4. In another embodiment of the invention, the front cover 2 is attached to the in-wall receptacle 1 with a hinge.

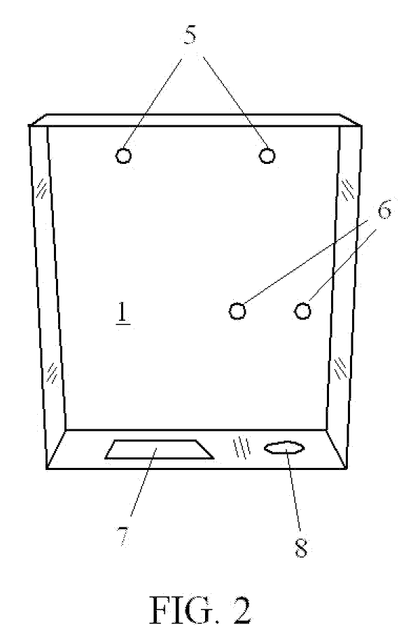

FIG. 2 is a front view of one embodiment of an in-wall receptacle 1. The in-wall receptacle 1 includes a back panel and four side walls, together forming a rectangular enclosure with the front remaining open. The in-wall receptacle 1 is large enough to have a wireless network device and a broadband modem 11 (or other network device) both attached to the back panel and still narrow and shallow enough to fit between two standard wall studs (no more than 14.5″ in width or 3.5″ deep). One present embodiment of the invention is approximately 11.5″ high by 10″ wide by 3″ deep. The in-wall receptacle 1 is made of polyvinyl or similar non-metallic material.

On the back panel of the in-wall receptacle 1 are router mounting screw holes 5 that align with the mounting slots on one or more wireless router 10 models. Also on the back panel of the in-wall receptacle 1 are broadband mounting screw holes 6 that align with the mounting slots on one or more broadband modems or similar broadband connection equipment.

On the bottom wall of the in-wall receptacle 1 is a gang box opening 7 to accommodate the installation of a gang box with an electrical outlet. Also on the bottom wall of the in-wall receptacle 1 is an opening for network connection cables 8 to accommodate the routing of a plurality of network cables to connect the wireless router 10 and broadband device to network infrastructure outside of the enclosure as needed.

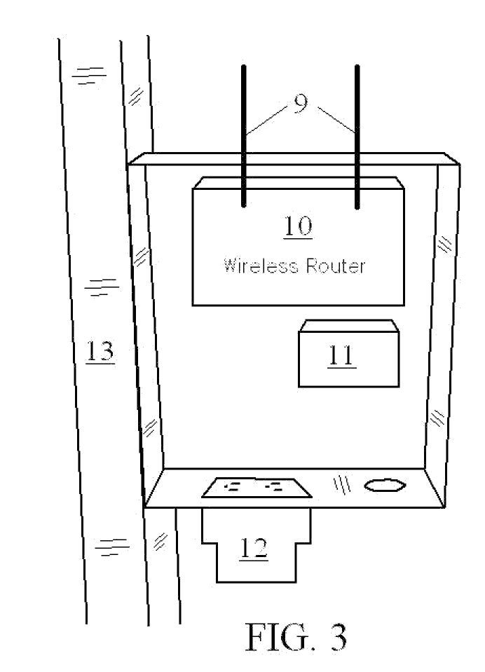

FIG. 3 depicts the front view of an in-wall receptacle 1 with a wireless router 10 and a broadband modem 11 affixed to the back panel, as well as the electrical gang box 12 with outlet in place.

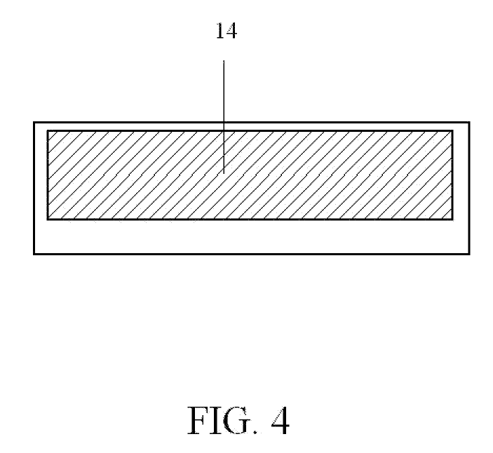

FIG. 4 is the top view of an in-wall receptacle 1 that shows the opening in the top 14 that allows the main body and/or antennas 9 of the wireless router 10 to protrude through the top of the receptacle into the open wall space if so desired.

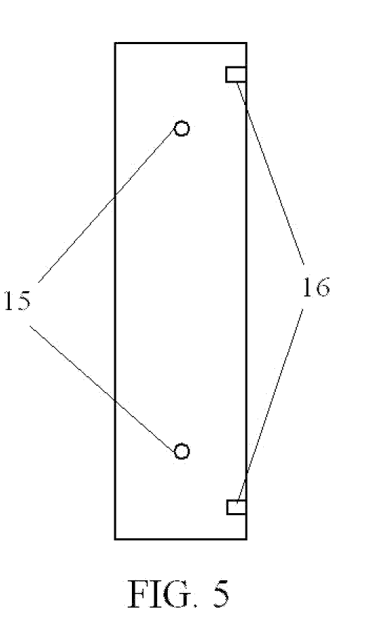

FIG. 5 depicts a view of the left side of an in-wall receptacle 1. There are two stud mounting holes 15 on each side. The front-edge alignment guides 16 are used to align the receptacle to the desired depth within the wall. The in-wall receptacle 1 is mounted to one wall stud 13 using two nails or two screws on one side of the receptacle.

For installation of the integrated Wi-Fi service enclosure, the first step is to identify the optimum location in the new structure from which the wireless network device will be able to provide optimum coverage. This location is usually in the physical center of the structure and is identified using radio signal measurement equipment. After the structure is framed and before the drywall is attached, the in-wall receptacle 1 is attached to a wall stud 13 in the desired location by placing one side of the receptacle against the side of the stud at the desired height and sliding the receptacle into the wall cavity until both front-edge alignment guides 16 press against the front surface of the stud. Once in place, the enclosure is affixed to the stud with two nails or screws through the stud mounting holes 15. Power is provided to the in-wall receptacle 1 by installing an electrical outlet into a gang box and attaching the gang box through the gang box opening 7. Network cables are run through the opening for network cables to provide connectivity between the in-wall enclosure and the broadband network (DSL, cable, WiMax, satellite) and any additional wired equipment on the local area network that is specified in the network design.

In this scenario, the wireless network device will be a wireless router 10 and the broadband network equipment will be a broadband modem 11. After the drywall is installed and painted, the next step is to attach the broadband modem 11 to the back panel of the in-wall receptacle 1. If the broadband device's mounting slots align with the broadband mounting screw holes 6, then one screw should be turned part-way into each of the two broadband mounting screw holes 6. Then, the mounting slots should be aligned with the two screws and the device pressed gently toward the back panel, and then slightly downward to secure it snugly against the back panel. If the mounting slots do not align, then a Velcro strip is attached to the back wall using one or two screws and the broadband mounting screw holes 6. The broadband device is then secured to the back panel within the receptacle using the Velcro strap.

The next step is to attach the wireless router 10 to the back panel of the in-wall receptacle 1. If the router's mounting slots align with the router mounting screw holes 5, then one screw should be turned part-way into each of the two router mounting screw holes 5. Then, the mounting slots should be aligned with the two screws and the router pressed gently toward the back panel, and then slightly downward to secure it snugly against the back panel. If the mounting slots do not align, then a Velcro strip is attached to the back wall using one or two screws and the router mounting screw holes 5. The wireless router 10 is then secured to the back panel within the receptacle using the Velcro strap.

Once everything is attached within the receptacle, an Ethernet cable is used to connect the wireless router 10 to the broadband modem 11. The cable providing connection to the broadband network that enters the in-wall receptacle 1 through the opening for network connection cables 8 should be connected to the broadband modem 11. And, the wireless router 10 can be connected to any other networked device outside the enclosure, if needed. Both the wireless router 10 and the broadband modem 11 should be plugged into the outlet in the gang box. The wireless router 10 should then be configured as needed to properly activate the Wi-Fi network. Once completed, the front cover 2 is installed by aligning the cover with the threaded inserts 4 and securing with the four cover screws 3, providing a smooth, professionally-finished appearance.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. An integrated wi-fi service enclosure for housing a wireless router and broadband connectivity equipment in a single non-metal, in-wall enclosure for streamlining deployment of wireless local area networks and providing maximum wireless coverage throughout a dwelling or business, comprising:
means for housing a wireless router and broadband connection equipment in a single enclosure;
means for covering the recessed enclosure and providing a smooth, professionally finished appearance on an interior wall;
means for enabling the body and/or antennas of the wireless network device to protrude out of the enclosure into the wall space if desired;
means for simplifying installation of the wireless network device into the receptacle;
means for simplifying installation of broadband equipment into the receptacle;
means for allowing the entrance and exit of networking cables to and from said in-wall receptacle;
means for providing power in the form of an electrical outlet terminated in the enclosure;
means for mounting the enclosure to a wall stud on either side utilizing screws or nails; and
means for simplifying the installation and ensuring that the enclosure is installed at the desired depth within the wall cavity, parallel to and just behind the drywall.

2. The integrated wi-fi service enclosure in accordance with claim 1, wherein said means for housing a wireless router and broadband connection equipment in a single enclosure comprises a polyvinyl or similar material in-wall receptacle.

3. The integrated wi-fi service enclosure in accordance with claim 1, wherein said means for covering the recessed enclosure and providing a smooth, professionally finished appearance on an interior wall comprises a front cover.

4. The integrated wi-fi service enclosure in accordance with claim 1, wherein said means for enabling the body and/or antennas of the wireless network device to protrude out of the enclosure into the wall space if desired comprises an opening in the top.

5. The integrated wi-fi service enclosure in accordance with claim 1, wherein said means for simplifying installation of the wireless network device into the receptacle comprises router mounting screw holes.

6. The integrated wi-fi service enclosure in accordance with claim 1, wherein said means for simplifying installation of broadband equipment into the receptacle comprises broadband mounting screw holes.

7. The integrated wi-fi service enclosure in accordance with claim 1, wherein said means for allowing the entrance and exit of networking cables to and from said in-wall receptacle comprises an opening for network connection cables.

8. The integrated wi-fi service enclosure in accordance with claim 1, wherein said means for providing power in the form of an electrical outlet terminated in the enclosure comprises a gang box opening.

9. The integrated wi-fi service enclosure in accordance with claim 1, wherein said means for mounting the enclosure to a wall stud on either side utilizing screws or nails comprises stud mounting holes.

10. The integrated wi-fi service enclosure in accordance with claim 1, wherein said means for simplifying the installation and ensuring that the enclosure is installed at the desired depth within the wall cavity, parallel to and just behind the drywall comprises front-edge alignment guides.

11. An integrated wi-fi service enclosure for housing a wireless router and broadband connectivity equipment in a single non-metal, in-wall enclosure for streamlining deployment of wireless local area networks and providing maximum wireless coverage throughout a dwelling or business, comprising:
a polyvinyl or similar material in-wall receptacle, for housing a wireless router and broadband connection equipment in a single enclosure;
a front cover, for covering the recessed enclosure and providing a smooth, professionally finished appearance on an interior wall;
an opening in the top, for enabling the body and/or antennas of the wireless network device to protrude out of the enclosure into the wall space if desired;
router mounting screw holes, for simplifying installation of the wireless network device into the receptacle;
broadband mounting screw holes, for simplifying installation of broadband equipment into the receptacle;
an opening for network connection cables, for allowing the entrance and exit of networking cables to and from said in-wall receptacle;
a gang box opening, for providing power in the form of an electrical outlet terminated in the enclosure;
stud mounting holes, for mounting the enclosure to a wall stud on either side utilizing screws or nails; and
front-edge alignment guides, for simplifying the installation and ensuring that the enclosure is installed at the desired depth within the wall cavity, parallel to and just behind the drywall.
